(19) United States
(12) Patent Application Publication
(10) Pub. No.: US 2025/0140773 A1
(43) Pub. Date: May 1, 2025

(54) ELECTRONIC PACKAGE ASSEMBLY AND A METHOD FOR FORMING THE SAME

(71) Applicant: JCET STATS ChipPAC Korea Limited, Incheon (KR)

(72) Inventors: SeungHyun LEE, Incheon (KR); HeeSoo LEE, Incheon (KR)

(21) Appl. No.: 18/926,424

(22) Filed: Oct. 25, 2024

(30) Foreign Application Priority Data
Oct. 27, 2023 (CN) 202311414659.7

(51) Int. Cl. H01L 25/00; H01L 21/48; H01L 21/56; H01L 23/00; H01L 23/538; H01L 23/552; H01L 25/10

(52) U.S. Cl. CPC H01L 25/50; H01L 21/4853; H01L 21/56; H01L 23/5385; H01L 24/81; H01L 25/105; H01L 23/552; H01L 24/16; H01L 2224/16225; H01L 2224/81986; H01L 2225/1041

(57) ABSTRACT

A method for forming the same is provided. The method comprises: providing a package substrate; attaching back conductive blocks onto a back surface of the package substrate via back solder bump; loading the package substrate on a first bottom chase with the back conductive blocks facing upward, and pressing, with a first top chase, the back conductive blocks against the first bottom chase to reshape the back solder bumps and horizontally align top surfaces of the back conductive blocks with each other; attaching front conductive blocks onto a front surface of the package substrate via front solder bumps; loading the package substrate on a second bottom chase with the front conductive blocks facing upward, and pressing, with a second top chase, the front conductive blocks against the second bottom chase to reshape the front solder bumps and horizontally align top surfaces of the front conductive blocks with each other.

### TECHNICAL FIELD

The present application generally relates to semiconductor packaging technology, and more particularly, to a method for forming an electronic package assembly and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, semiconductor packages are fabricated into smaller sizes to bring about higher density of electronic components. Typically, the semiconductor packages may include key functional modules, such as semiconductor chips and interconnection structures. However, it is noted that certain interconnection formation processes, such as stacking multiple layers of solder balls in a single through hole for higher interconnect structures, particularly for multiple-tier packages, may be complicated and not cost effective. Also, such complicated process may adversely affect the yield of the electronic packages incorporating such interconnection structures.

Therefore, a need exists for a method for forming an electronic package assembly with a simple process and an improved yield.

### SUMMARY OF THE INVENTION

An objective of the present application is to provide a method for forming an electronic package assembly with a simple process and an improved yield.

According to an aspect of the present application, an electronic package assembly and a method for forming the same is provided. The method comprises: providing a package substrate having a front surface and a back surface, wherein multiple sets of front conductive pads are formed on the front surface and multiple sets of back conductive pads are formed on the back surface; attaching back conductive blocks onto the back surface of the package substrate via back solder bumps, wherein each of the back conductive blocks is aligned with one of the sets of back conductive pads; loading the package substrate on a first bottom chase with the back conductive blocks facing upward, and pressing, with a first top chase, the back conductive blocks against the first bottom chase to reshape the back solder bumps and horizontally align top surfaces of the back conductive blocks with each other; forming a back mold cap between the package substrate and the first top mold chase; attaching front conductive blocks onto the front surface of the package substrate via front solder bumps, wherein each of the front conductive blocks is aligned with one of the sets of front conductive pads; loading the package substrate on a second bottom chase with the front conductive blocks facing upward, and pressing, with a second top chase, the front conductive blocks against the second bottom chase to reshape the front solder bumps and horizontally align top surfaces of the front conductive blocks with each other; and forming a front mold cap between the package substrate and the second top mold chase.

According to another aspect of the present application, another electronic package assembly and a method for forming the same is provided. The method comprises: providing a package substrate having a front surface and a back surface, wherein multiple sets of front conductive pads are formed on the front surface and multiple sets of back conductive pads are formed on the back surface; attaching front conductive blocks onto the front surface of the package substrate via front solder bumps, wherein each of the front conductive blocks is aligned with one of the sets of front conductive pads; attaching back conductive blocks onto the back surface of the package substrate via back solder bumps, wherein each of the back conductive blocks is aligned with one of the sets of back conductive pads; loading the package substrate between a top chase and a bottom chase, and pressing the front and back conductive blocks against the package substrate with the top chase and the bottom chase to reshape the front and back solder bumps, horizontally align top surfaces of the front conductive blocks with each other and horizontally align top surfaces of the back conductive blocks with each other; forming a front mold cap between the front surface of the package substrate and the top chase; and forming a back mold cap between the back surface of the package substrate and the bottom chase.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1I illustrate various steps of a method for forming an electronic package assembly according to a first embodiment of the present application.

FIGS. 2A to 2H illustrate various steps of a method for forming an electronic package assembly according to a second embodiment of the present application.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, an approach to form higher interconnection structures in a semiconductor package such as in a mold cap of such semiconductor package is stacking multiple layers of solder balls in a single through hole. However, such approach may be complicated in process especially for multiple-tier packages. As an alternative approach, preformed conductive blocks such as e-bars, which have multiple conductive pillars built in a single block, may be mounted in a through hole or cavity on a package substrate to form a thicker interconnection structure. The inventors of the present application noticed that semiconductor packages incorporating preformed conductive blocks have a relatively lower yield and are low in reliability. After an investigation of samples of the semiconductor packages, the inventors have identified that for Double-Side Molded (DSM) packages having conductive blocks on both sides, there may be a significant height difference between two or more preformed conductive blocks on each side of a same package substrate, due to a difference in the size and height of solder bumps that mount conductive blocks on each surface of the package substrate. To address this issue, a new method for attaching conductive blocks on a DSM package substrate is provided, which introduces one or two pressing steps to obtain solder bumps on each side of the package substrate with a substantially uniform height. The method can be used in forming an electronic package assembly such as a double side molded (DSM) package or a multiple-tier package as a portion of the steps of the package forming process.

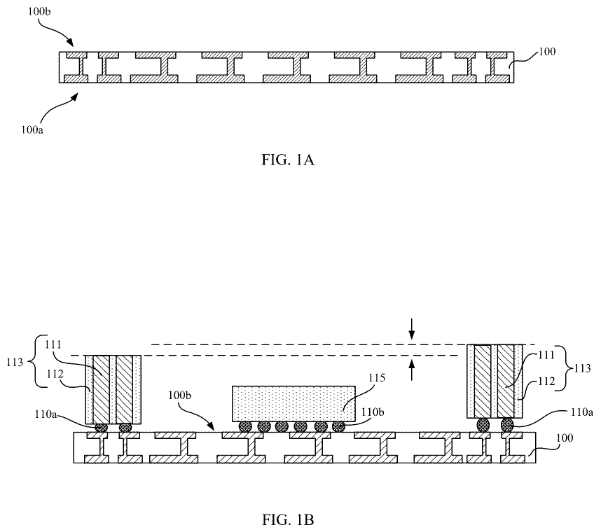

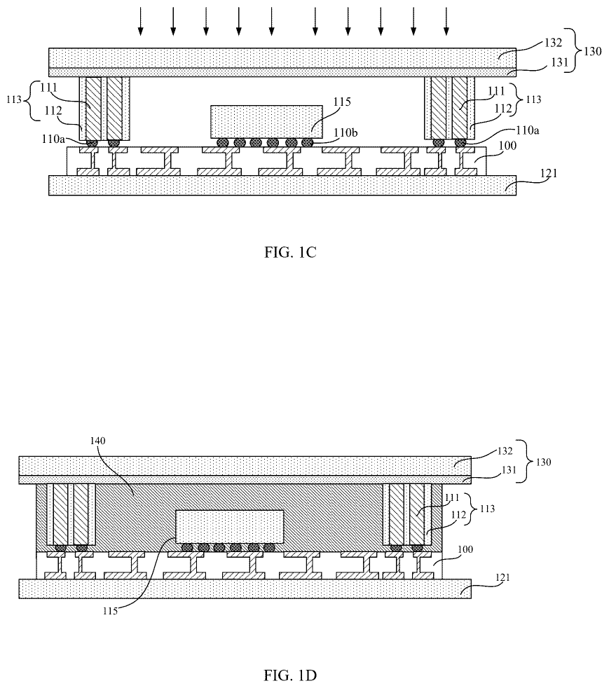

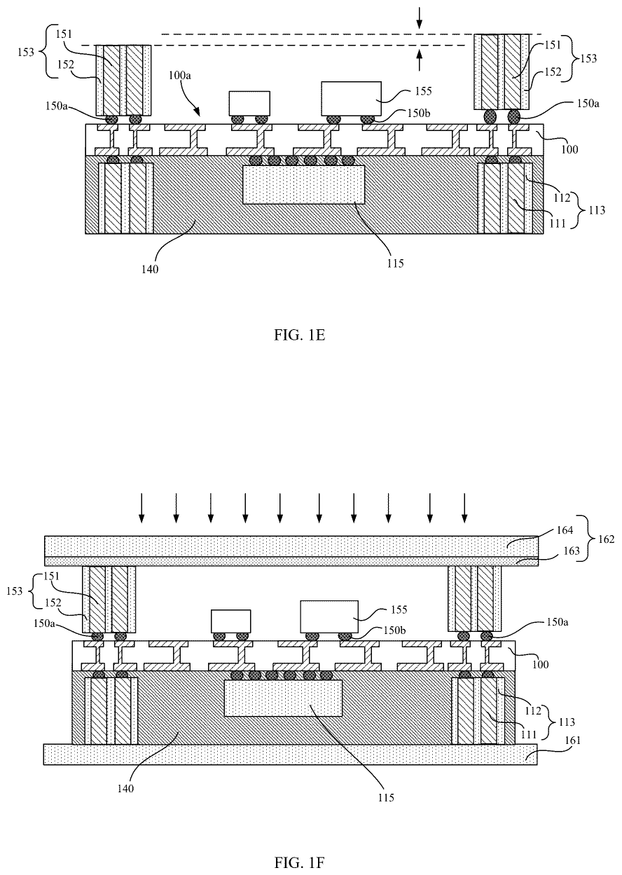

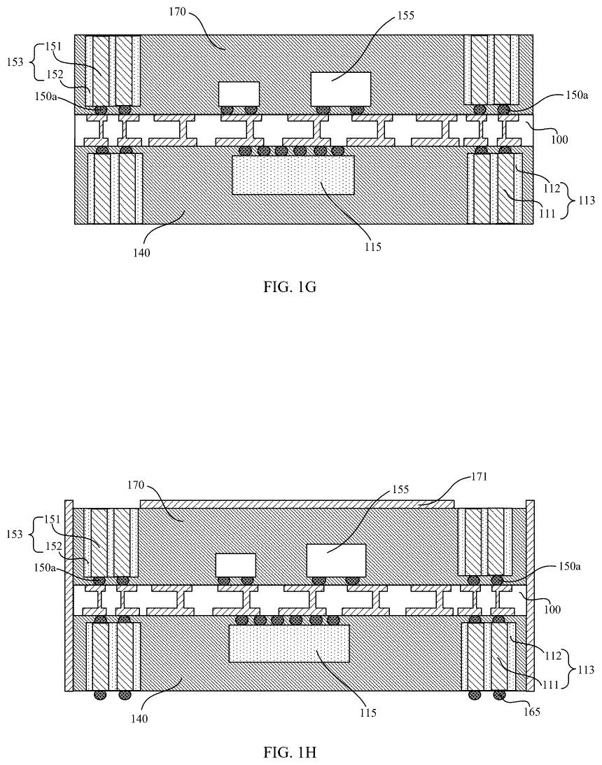

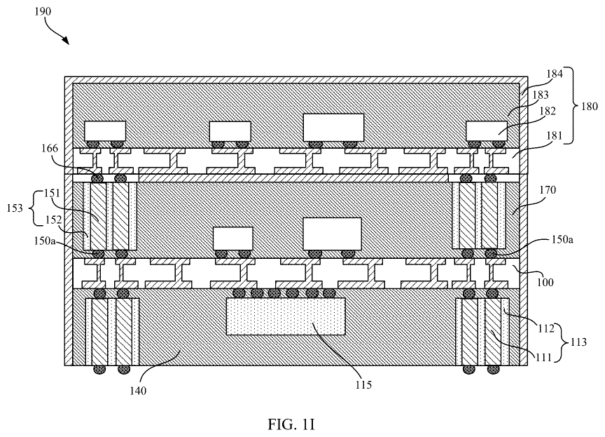

FIGS. 1A to 1I illustrate various steps of a method for forming an electronic package assembly according to a first embodiment of the present application. In the following, the method will be described with reference to FIGS. 1A to 1I in more details.

As shown in FIG. 1A, a package substrate 100 is provided with embedded interconnect wires. The package substrate 100 includes a front surface 100a and a back surface 100b, which are opposite to each other. In some embodiments, the electronic package assembly may include a DSM package, and the front surface 100a and the back surface 100b of the package substrate 100 may both serve as platforms where electronic component(s) and conductive blocks can be mounted. Multiple sets of front conductive pads (not shown) may be formed on the front surface 100a and multiple sets of back conductive pads (not shown) may be formed on back surface 100b of the package substrate 100 for the mounting of the electronic components and the conductive blocks. It can be appreciated that the multiple sets of front and back conductive pads may be exposed portions of interconnect wires formed within the package substrate 100.

As shown in FIG. 1B, a solder material is deposited onto the back surface 100b of the package substrate 100 to form a plurality of back solder bumps 110a on the multiple sets of back conductive pads. The solder material can be Al, Sn, Ni, Au, Ag, lead (Pb), bismuth (Bi), Cu, or combinations thereof, with an optional flux solution.

Next, at least one back electronic component 115 is attached onto the back surface 100b of the package substrate 100 via additional solder bumps 110b, thus forming electrical connection between the interconnect wires and the at least one back electronic component 115. In some embodiments, the back electronic component 115 may be semiconductor chips, resistors, capacitors or smaller semiconductor packages. It can be appreciated that more back electronic components 115 may be mounted onto the back surface 100b. Furthermore, multiple back conductive blocks 113 are also attached onto the back surface 100b of the package substrate 100 via the back solder bumps 110a, thus forming electrical connection between interconnect wires and the back conductive blocks 113. The back conductive blocks 113 may be e-bar blocks that include built-in conductive pillars 111 such as copper pillars and an insulative base material separating the copper pillars from each other. Two or more back conductive blocks 113 may be mounted on the back surface 100b at different locations, for example, at two opposite sides of the back electronic component 115. In the embodiment, the multiple back conductive blocks 113 are thicker than the back electronic component 115. In this way, the electronic package assembly may be electrically connected with other external electronic devices via the multiple back conductive blocks 113 while, at the same time, keeping the back electronic component 115 isolated from other devices. In some embodiments, the back conductive blocks 113 and the at least one back electronic component 115 can be attached onto the back surface 100b of the package substrate 100 simultaneously, while in some other embodiments, the back conductive blocks 113 may be attached onto the back surface 100b of the package substrate 100 before or after the back electronic component 115 is attached.

Furthermore, each of the back conductive blocks 113 is aligned with one of the sets of back conductive pads. In this example, the back conductive blocks 113 are positioned at two opposite sides of the back electronic component 115, which are separated apart with a relatively long distance. However, it can be appreciated that the back electronic component 115 and the back conductive blocks 113 may be attached onto the back surface 100b of the package substrate 100 with a different distance and arrangement. Additionally, more back conductive blocks 113 may be attached onto the back surface 100b, depending on the actual needs of the electronic package assembly.

Still referring to FIG. 1B, the back conductive blocks 113 may include e-bar blocks. In this example, each e-bar block further includes multiple conductive pillars 111 and a dielectric layer 112 surrounding the conductive pillars 111. The dielectric layer 112 includes materials such as an insulative polymeric material or composite. To be more specific, bottom surfaces of the conductive pillars 111 are exposed from a bottom surface of the dielectric layer 112 for contacting the back solder bumps 110a. Similarly, top surfaces of the conductive pillars 111 are exposed from a top surface of the dielectric layer 112 for electrical contact purpose. For example, additional conductive pads may be formed on the conductive pillars 111, and additional solder bumps may be disposed on the conductive pads subsequently for contacting an external device. In some embodiments, the conductive pillars 111 in some back conductive blocks 113 are electrically connected with each other. In some other embodiments, the conductive pillars 111 in some back conductive blocks 113 are not electrically connected with each other but electrically isolated from each other for separate electrical paths. Furthermore, the number of the conductive pillars 111 included in each of the back conductive blocks 113 may vary according to actual needs of the electronic package assembly.

As mentioned above, the back conductive blocks 113 at different positions on the back surface 100b of the package substrate 100 may have different heights due to the unevenness of the back surface 100b, the nonuniformity of the forming process of the back solder bumps 110a and the inconformity of the attaching process of the back conductive blocks 113 onto the package substrate 100. For example, the heights of the back solder bumps 110a under the back conductive block 113 on the left of the back electronic component 115 may be different from the heights of the back solder bumps 110a under the back conductive block 113 on the right of the back electronic component 115, rendering a height difference between the top surfaces of the back conductive blocks 113. Also, the top surfaces of the back conductive blocks 113 may be tilted. A pressing process may be conducted to address this issue.

As shown in FIG. 1C, the package substrate 100 is loaded on a first bottom chase 121 with the back conductive blocks 113 facing upward. The first bottom chase 121 may be used for placing the package substrate 100 and providing upward supporting forces when the back conductive blocks 113 are pressed against the first bottom chase 121. In a preferred embodiment, a length of the first bottom chase 121 in a horizontal direction may be greater than that of the package substrate 100 to provide sufficient and balanced forces to support the package substrate 100.

Next, the back conductive blocks 113 are pressed against the first bottom chase 121 with a first top chase 130 to reshape the back solder bumps 110a. In this example, all of the multiple back conductive blocks 113 are in contact with the same surface of the first top chase 130 to receive forces simultaneously from the first top chase 130. During the pressing process, the back solder bumps 110a may be substantially flattened, for example, from a circular shape to an oval shape or even a disk shape, thereby resulting in reduced distances from the top surfaces of the back conductive blocks 113 to the back surface 100b of the package substrate 100 in a controlled way. After the pressing step, the top surfaces of the multiple back conductive blocks 113 are horizontally aligned with each other, which allows for enhanced uniformity of the structures of the back conductive blocks 113. It can be appreciated that, the amount of reduction in the height of the back solder bumps 110a may be different, depending on the original heights of the back solder bumps 110a. The higher the original height is, the more compression or reduction in height is. Also, since the back conductive blocks 113, especially the conductive pillars 111 inside, may have a stiffness greater than that of the back solder bumps 110a, the pressing process may not reshape the back conductive blocks 113.

In the embodiment shown in FIG. 1C, the first top chase 130 may include a first base plate 132 and a first flexible film 131, and the first flexible film 131 is in contact with the top surfaces of the multiple back conductive blocks 113 during the pressing step. The first flexible film 131 may serve as a release film, which provides a buffer between the first base plate 132 and the back conductive blocks 113 to protect the back conductive blocks 113 from potential damage during the pressing step. The first flexible film 131 material may include foamed plastic, rubber or the like. In some embodiments, the first flexible film 131 can be a multi-layered structure which provides a more delicate buffer between the first base plate 132 and the back conductive blocks 113. In some other embodiments, the flexible film 131 can be omitted, where the first base plate 132 may directly contact the surfaces of the multiple back conductive blocks 113. In this example, since the multiple back conductive blocks 113 are thicker than the back electronic component 115, the back electronic component 115 is not affected when the multiple back conductive blocks 113 are pressed by the first top chase 130. Accordingly, when the pressing step is completed, a gap may exist between the top surface of the back electronic component 115 and the bottom surface of the first top chase 130 such that the back electronic component 115 can be fully encapsulated subsequently.

Furthermore, in some embodiments, the bottom surface of the first top chase 130 is an extended flat surface. In some other embodiments, the first top chase 130 may include a cavity with a bottom surface within the first top chase 130, and the top surfaces of the multiple back conductive blocks 113 are in contact with the bottom surface of the cavity. In some examples, the cavity of the first top chase 130 may serve as an injection molding chamber for a subsequent molding process. In other words, both the pressing process and the molding process may be implemented by a single set of tools.

It can be appreciated that since the pressing step may reduce the heights of the back solder bumps 110a, respective cross sections of the solder bumps 110a in the horizontal direction may expand for some extent. However, the pressing step may be implemented that the back solder bumps 110a on each set of back conductive pads are reshaped but not connected with each other to avoid potential short-circuit risks. Therefore, during the pressing step, the pressure and forces applied onto the first top chase 130 should be determined based on the space and distance between adjacent back solder bumps 110a. In some embodiments, a stopper may be provided between the first top and first bottom chase 130, 121 to limit a maximum distance the first top chase 130 can move toward the first bottom chase 121.

It can be appreciated that the pressing step may be implemented when a reflowing of the back solder bumps 110a is being implemented. Also, the back solder bumps 110a may exhibit deformable characteristics which may be reshaped by external forces.

Next, as shown in FIG. 1D, a molding material is formed between the first top chase 130 and the back surface 100b of the package substrate 100 to form a back mold cap 140 which encapsulates the multiple back conductive blocks 113 and the back electronic component 115. In some embodiments, the back mold cap 140 is formed using a molding process such as a film-assisted molding (FAM) process, which covers the top and lateral surfaces of the back electronic component 115 and the lateral surfaces of the back conductive blocks 113 for encapsulation. The molding material is first liquefied by heat and pressure, and then forced into a closed mold cavity (e.g., the cavity in the first top chase 130) and held there under additional heat and pressure until all material is solidified. The FAM process enables easy release of the encapsulated package from the chases since the molding material contacts the assisting films instead of the metal mold chase. Also, the films may function as soft cushions, resulting in less wear of mold parts. The molding material used in the FAM process may include very sticky and liquid silicone materials. It can be appreciated that the assisting films may include the first flexible film 131 of the first top chase 130 when the first top chase 130 is used for both pressing and molding. In some other embodiments, another set of mold chases may be used for the molding process, instead of the first top chase 130 and the first bottom chase 121 that are used in the pressing process. Moreover, in some other embodiments, the back mold cap 140 can also be formed using other molding technologies. After the formation of the back mold cap 140, the top surfaces of the back conductive blocks 113 are exposed from a top surface of the back mold cap 140.

As shown in FIG. 1E, the package substrate 100 and the various components thereon may be removed from the first top chase 130 and the first bottom chase 121. The package substrate 100 may then be flipped over for further attachment of other components or blocks on its front surface 100a. In particular, a plurality of front solder bumps 150a may be formed on the multiple sets of front conductive pads. Then multiple front conductive blocks 153 are attached onto the front surface 100a of the package substrate 100 via the front solder bumps 150a, thus forming electrical connection between interconnect wires and the front conductive blocks 153. Each of the front conductive blocks 153 is aligned with one of the sets of front conductive pads. The front conductive blocks 153 may be e-bar blocks that each of them may include multiple conductive pillars 151 and a dielectric layer 152 surrounding the conductive pillars 151. To be more specific, bottom surfaces of the conductive pillars 151 are exposed from a bottom surface of the dielectric layer 152 for contacting the front solder bumps 150a. Similarly, top surfaces of the conductive pillars 151 are exposed from a top surface of the dielectric layer 152 for electrical contact purpose. Furthermore, at least one front electronic component 155 may be attached onto the front surface 100a of the package substrate 100 via additional solder bumps 150b, and the front conductive blocks 153 are thicker than the front electronic component 155. The detailed attachment processes and structures of the front conductive blocks 153, the front solder bumps 150a and the front electronic component 155 may be similar to those illustrated in the attachment processes and structures of the back conductive blocks 113, the back solder bumps 110a and the back electronic component 115 shown in FIG. 1B.

Still referring to FIG. 1E, the front conductive blocks 153 at different positions on the front surface 100a of the package substrate 100 may have different heights. For example, the heights of the front solder bumps 150a under the front conductive blocks 153 on the left of the front electronic component(s) 155 may be different from the heights of the front solder bumps 150a under the front conductive blocks 153 on the right of the front electronic component 155, rendering a height difference between the top surfaces of the front conductive blocks 153. Also, the top surfaces of the front conductive blocks 153 may be tilted. A pressing process may be conducted to address this issue.

As shown in FIG. 1F, the package substrate 100 is loaded on a second bottom chase 161 with the front conductive blocks 153 facing upward. Then the front conductive blocks 153 are pressed against the second bottom chase 161 with a second top chase 162 to reshape the front solder bumps 150a. In the embodiment shown in FIG. 1F, the second top chase 162 may include a second base plate 164 and a second flexible film 163, and the second flexible film 163 is in contact with the top surfaces of the multiple front conductive blocks 153 during the pressing step, serving as a release film which provides a buffer between the second base plate 164 and the front conductive blocks 153. After the pressing step, the top surfaces of the multiple front conductive blocks 153 are horizontally aligned with each other, and the front solder bumps 150a on each set of front conductive pads are reshaped but not connected with each other. The details of the pressing step may be similar to that illustrated in the pressing step shown in FIG. 1C.

Next, as shown in FIG. 1G, a front mold cap 170 is formed between the package substrate 100 and the second top chase 162 to encapsulate the multiple front conductive blocks 153 and the at least one front electronic component 155. The top surfaces of the front conductive blocks 153 are exposed from a top surface of the front mold cap 170. The detailed formation process of the front mold cap 170 may be similar to that illustrated in the formation process of the back mold cap 140 shown in FIG. 1D. Afterwards, the package substrate 100 and the various components thereon may be removed from the second top chase 162 and the second bottom chase 161.

Next, as shown in FIG. 1H, a shielding layer 171 may be formed at least on the flat top surface of the front mold cap 170, which may help to protect the other parts of the electronic package assembly from electromagnetic interferences. The shielding layer 171 above the top surfaces of the front conductive blocks 153 is removed to expose the top surfaces of the front conductive blocks 153 for mounting of external electronic devices. In some examples, the shielding layer 171 may extend to the structures adjacent to the mold caps, and/or other surfaces (e.g., lateral surfaces) of the front mold cap 170, the back mold cap 140 and the package substrate 100. In some embodiments, the package substrate 100 may be singulated into smaller units before or after the formation of the shielding layer 171. Next, solder bumps 165 may be formed on the top surfaces of the back conductive blocks 113 for electrical connection purpose.

Next, as shown in FIG. 1I, additional solder bumps 166 may be formed onto the top surfaces of the front conductive blocks 153. Next, an upper electronic component 180 may be mounted onto the top surfaces of the front conductive blocks 153 via the additional solder bumps 166 to form a three-tier electronic package assembly 190. In this embodiment, the upper electronic component 180 may be a pre-molded electronic package, which may be fabricated by the following process: providing an additional package substrate 181 having a front surface; mounting at least one electronic component 182 onto the front surface of the additional package substrate 181; forming a mold cap 183 to encapsulate the at least one electronic component 182; forming a shielding layer 184 on the top surface and lateral surfaces of the mold cap 183 or electromagnetic interferences prevention. In some other embodiments, it can be appreciated that other various types of electronic modules may be mounted onto the top surfaces of the front conductive blocks 153.

In the embodiment shown in FIG. 1I, the electronic package assembly 190 may include a double side molded (DSM) package having conductive blocks and electronic components on two opposite surfaces of the package substrate 100. After two pressing steps, the top surfaces of the front conductive blocks 153 are horizontally aligned with each other, and the top surfaces of the back conductive blocks 113 are also horizontally aligned with each other, thus allowing for extra enhanced uniformity of the conductive blocks on both sides of the package substrate 100. Therefore, the top surfaces of the front conductive blocks 153 and the top surfaces of the back conductive blocks 113 may both serve as flat platforms for mounting of external electronic modules, such as the upper electronic component 180, further improving the overall uniformity of the three-tier electronic package assembly 190 and reducing the potential structural defects in the following processes.

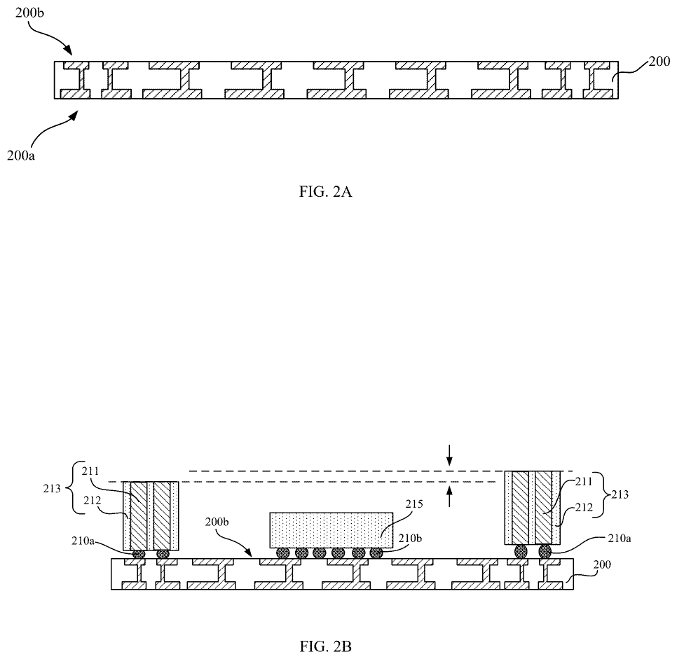

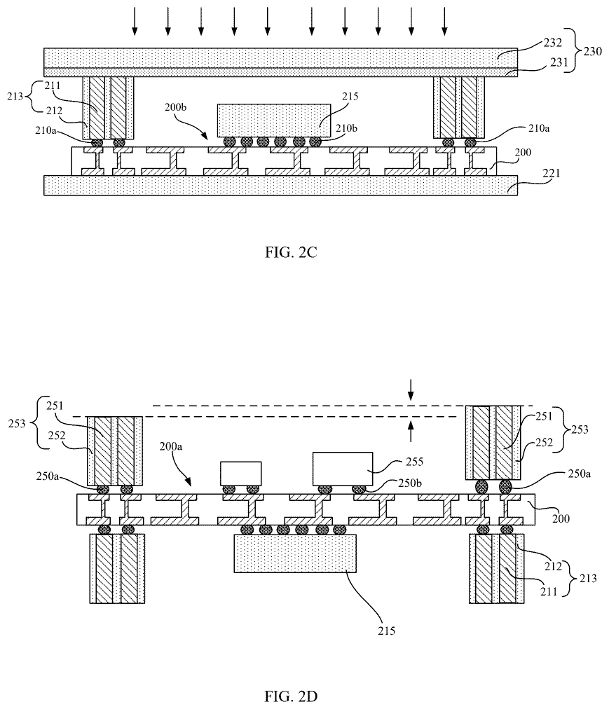

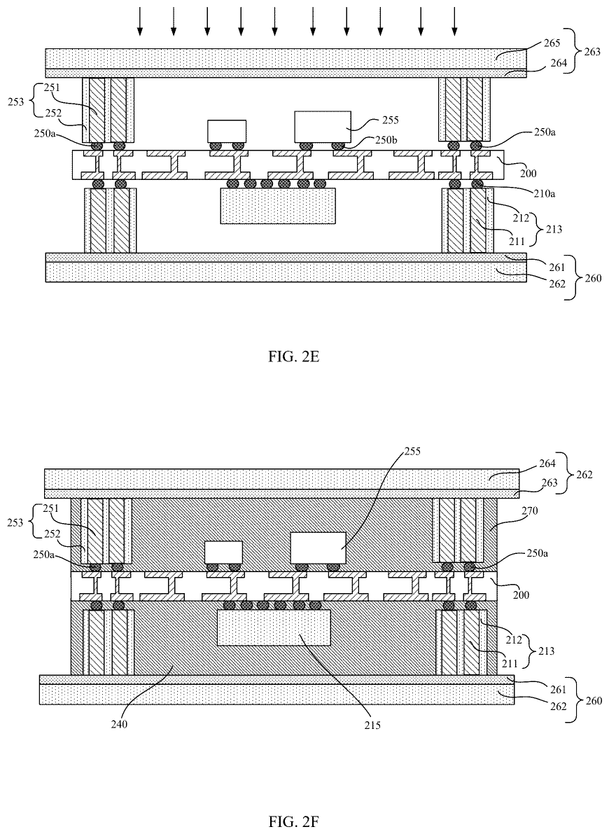

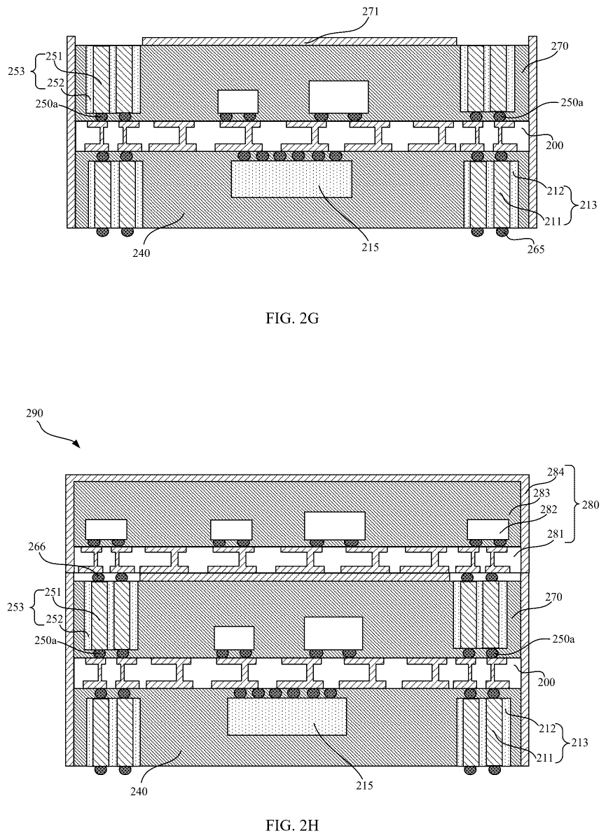

FIGS. 2A to 2H illustrate various steps of a method for forming an electronic package assembly according to a second embodiment of the present application. In the following, the method will be described with reference to FIGS. 2A to 2H in more details.

As shown in FIG. 2A, a package substrate 200 is provided with embedded interconnect wires. The package substrate 200 includes a front surface 200a and a back surface 200b, which are opposite to each other. Multiple sets of front conductive pads are formed on the front surface 200a and multiple sets of back conductive pads are formed on the back surface 200b. It can be appreciated that the multiple sets of the front and back conductive pads may be exposed portions of interconnect wires formed within the package substrate 200.

As shown in FIG. 2B, back conductive blocks 213 are attached onto the back surface 200b of the package substrate 200 via back solder bumps 210a, and each of the back conductive blocks 213 is aligned with one of the sets of back conductive pads. The back conductive blocks 213 may be e-bar blocks, each of which may further include multiple conductive pillars 211 and a dielectric layer 212 surrounding the conductive pillars 211. Furthermore, at least one back electronic component 215 is attached onto the back surface 200b of the package substrate 200 via additional solder bumps 210b. The detailed formation processes and structures of the back conductive blocks 213, the back solder bumps 210a and the back electronic component 215 may be similar to those illustrated in the formation processes and structures of the back conductive blocks 113, the back solder bumps 110a and the back electronic component 115 shown in FIG. 1B.

Still referring to FIG. 2B, the back conductive blocks 213 at different positions on the back surface 200b of the package substrate 200 may have different heights due to different heights of the back solder bumps 210a under the corresponding back conductive blocks 213. A pressing process may be conducted to address this issue.

Next, as shown in FIG. 2C, the package substrate 200 is loaded on a bottom chase 221 with the back conductive blocks 213 facing upward. The back conductive blocks 213 are pressed against the bottom chase 221 with a top chase 230 to reshape the back solder bumps 210a. To be more specific, the top chase 230 may include a base plate 232 and a flexible film 231, and the flexible film 231 is in contact with the top surfaces of the multiple back conductive blocks 213 during the pressing step, serving as a release film which provides a buffer between the base plate 232 and the back conductive blocks 213. After the pressing step, the top surfaces of the multiple back conductive blocks 213 are horizontally aligned with each other, which allows for enhanced uniformity of the structures of the back conductive blocks 213. The back solder bumps 210a on each set of back conductive pads are reshaped but not connected with each other. In some other embodiments, the pressing step illustrated in FIG. 2C may be omitted or performed later as described below.

Next, as shown in FIG. 2D, the package substrate 200 and the various components thereon may be removed from the top chase 230 and the bottom chase 221. The package substrate 200 may then be flipped over for further attachment of other components or blocks on its front surface 200a. In particular, a plurality of front solder bumps 250a may be formed on the multiple sets of front conductive pads. Then multiple front conductive blocks 253 are attached onto the front surface 200a of the package substrate 200 via the front solder bumps 250a, and each of the front conductive blocks 253 is aligned with one of the sets of front conductive pads. The front conductive blocks 253 may be e-bar blocks that each of them may include multiple conductive pillars 251 and a dielectric layer 252 surrounding the conductive pillars 251. To be more specific, bottom surfaces of the conductive pillars 251 are exposed from a bottom surface of the dielectric layer 252 for contacting the front solder bumps 250a. Similarly, top surfaces of the conductive pillars 251 are exposed from a top surface of the dielectric layer 252 for electrical contact purpose. Furthermore, at least one front electronic component 255 may be attached onto the front surface 200a of the package substrate 200 via additional solder bumps 250b, and the front conductive blocks 253 are thicker than the front electronic component 255. The detailed attachment processes and structures of the front conductive blocks 253, the front solder bumps 250a and the front electronic component 255 may be similar to those illustrated in the attachment processes and structures of the front conductive blocks 153, the front solder bumps 150a and the front electronic component 155 shown in FIG. 1E.

Similarly, as shown in FIG. 2D, the front conductive blocks 253 at different positions on the front surface 200a of the package substrate 200 may have different heights due to the different heights of the front solder bumps 250a under the corresponding front conductive blocks 253. A pressing process may be conducted to address this issue.

As shown in FIG. 2E, the package substrate 200 is loaded between a top chase 263 and a bottom chase 260. Next, the front and back conductive blocks 253, 213 are pressed against the package substrate 200 with the top chase 263 and the bottom chase 260 to reshape the front and back solder bumps 250a, 210a. After the pressing step, the top surfaces of the multiple back conductive blocks 213 are horizontally aligned with each other, and the top surfaces of the front conductive blocks 253 are horizontally aligned with each other. To be more specific, during the pressing step, the front solder bumps 250a may be substantially flattened, for example, from a circular shape to an oval shape or even a disk shape, thereby resulting in reduced distances from the top surfaces of the front conductive blocks 253 to the front surface 200a of the package substrate 200 in a controlled way. The amount of reduction in the height of the front solder bumps 250a may be different, depending on the original heights of the front solder bumps 250a. Furthermore, since the top surfaces of back conductive blocks 213 have been aligned during the prior pressing step illustrated in FIG. 2C, now the pressing step illustrated in FIG. 2E may continue to reduce the heights of the back solder bumps 210a by the same extent, continuously keeping the top surfaces of the back conductive blocks 213 horizontally aligned with each other. In this way, the top surfaces of the front conductive blocks 253 and the top surfaces of the back conductive blocks 213 are aligned respectively, which allows for better uniformity of the conductive blocks as well as more reliability and more flexibility of the pressing process. In some embodiments, the front solder bumps 250a on each set of front conductive pads and the back solder bumps 210a on each set of back conductive pads are reshaped but not connected with each other after the step for pressing the front and back conductive blocks 253 and 213. It can also be appreciated that the top surfaces of the back conductive blocks 213 may also be realigned during the pressing step in case the back solder bumps 210a have been reshaped after the prior pressing step illustrated in FIG. 2C.

In some other embodiments, the prior pressing step illustrated in FIG. 2C may not be performed before the attachment of the front conductive blocks 253. Therefore, the back conductive blocks 213 at different positions on the back surface 200b of the package substrate 200 may also have different heights due to the height differences of the back solder bumps 210a under the corresponding back conductive blocks 213. Therefore, during the pressing step as shown in FIG. 2E, the back solder bumps 210a and the front solder bumps 250a may be pressed and flattened simultaneously. The amount of reduction in the height of the back solder bumps 210a may be different, depending on the original heights of the back solder bumps 210a; and similarly, the amount of reduction in the height of the front solder bumps 250a may also be different. In this way, distances from the top surfaces of the back conductive blocks 213 to the back surface 200b of the package substrate 200 as well as the distances from the top surfaces of the front conductive blocks 253 to the front surface 200a may both be reduced at the same time and in a controlled way, thereby simplifying the pressing process.

Additionally, the top chase 263 may include a top base plate 265 and a top flexible film 264, and the top flexible film 264 is in contact with the top surfaces of the front conductive blocks 253 during the pressing step, serving as a release film which provides a buffer between the top base plate 265 and the front conductive blocks 253. Also, the bottom chase 260 includes a bottom base plate 262 and a bottom flexible film 261, and the bottom flexible film 261 is in contact with the top surfaces of the back conductive blocks 213 during the pressing step, serving as a release film which provides a buffer between the bottom base plate 262 and the back conductive blocks 213. It should be noted that the top chase 263 and the bottom chase 260 used in the pressing step illustrated in FIG. 2E may be different from the top chase 230 and the bottom chase 221 used in the pressing step illustrated in FIG. 2C. In other embodiments, the top chase 263 and the bottom chase 260 used in the pressing step illustrated in FIG. 2E may be the same as the top chase 230 and the bottom chase 221 used in the pressing step illustrated in FIG. 2C, i.e., the chases are used twice in the pressing steps.

Next, as shown in FIG. 2F, a front mold cap 270 is formed between the front surface 200a of the package substrate 200 and the top chase 262, covering the top and lateral surfaces of the front electronic component 255 and the lateral surfaces of the front conductive blocks 253 for encapsulation. Similarly, a back mold cap 240 is formed between the back surface 200b of the package substrate 200 and the bottom chase 260, covering the top and lateral surfaces of the back electronic component 215 and the lateral surfaces of the back conductive blocks 213 for encapsulation. The top surfaces of the front conductive blocks 253 are exposed from a top surface of the front mold cap 270, and the top surfaces of the back conductive blocks 213 are exposed from a top surface of the back mold cap 240. In some embodiments, the front mold cap 270 and the back mold cap 240 may be formed simultaneously, which further simplifies the molding process. In some other embodiments, the front mold cap 270 may be formed before or after the formation of the back mold cap 240.

Furthermore, in some embodiments, the front mold cap 270 and the back mold cap 240 is formed using a molding process such as a film-assisted molding (FAM) process. In some other embodiments, the front mold cap 270 and the back mold cap 240 can also be formed using other molding technologies. The detailed formation process of the front mold cap 270 and the back mold cap 240 may be similar to those illustrated in the formation process of the front mold cap 170 and the back mold cap 140 shown in FIGS. 1D and 1G.

Next, as shown in FIG. 2G, a shielding layer 271 may be formed at least on the flat top surface of the front mold cap 270, which may help to protect the other parts of the electronic package assembly from electromagnetic interferences. The shielding layer 271 above the top surfaces of the front conductive blocks 253 are removed to expose the top surfaces of the front conductive blocks 253 for mounting of external electronic devices. In some examples, the shielding layer 271 may extend to the structures adjacent to the mold caps, and/or other surfaces (e.g., lateral surfaces) of the front mold cap 270, the back mold cap 240 and the package substrate 200. In some embodiments, the package substrate 200 may be singulated into smaller units before or after the formation of the shielding layer 271. Next, solder bumps 265 may be formed on the top surfaces of the back conductive blocks 213 for electrical connection purpose.

Next, as shown in FIG. 2H, additional solder bumps 266 may be formed onto the top surfaces of the front conductive blocks 253. Next, an upper electronic component 280 may be mounted onto the top surfaces of the front conductive blocks 253 via the additional solder bumps 266 to form a three-tier electronic package assembly 290. In this embodiment, the upper electronic component 280 may be a pre-molded electronic package, which may be fabricated by the following process: providing an additional package substrate 281 having a front surface; mounting at least one electronic component 282 onto the front surface of the additional package substrate 281; forming a mold cap 283 to encapsulate the at least one electronic component 282; forming a shielding layer 284 on the top surface and lateral surfaces of the mold cap 283 for electromagnetic interferences prevention. In some other embodiments, it can be appreciated that other various types of electronic modules may be mounted onto the top surfaces of the front conductive blocks 253.

In some embodiments, the electronic package assembly 290 can be applied in any electronic devices which desire conductive blocks with uniform structures and improved yield, such as in high-sensitive sensors, precise integrated circuit devices or the like.

It can be appreciated that the process of pressing the solder bumps may be implemented in various other applications, other than the semiconductor package. For example, the method may not include the process of attaching electronic components or onto the front surface and the back surface of the package substrate, which thereby only forms conductive blocks on a front surface and a back surface of a package substrate. The top surfaces of the multiple front conductive blocks are aligned horizontally with each other, and the top surfaces of the multiple back conductive blocks are aligned horizontally with each other as well.

While the exemplary method for forming an electronic package assembly of the present application is described in conjunction with corresponding figures, it will be understood by those skilled in the art that modifications and adaptations to the method for forming an electronic package assembly may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic package assembly, comprising:
providing a package substrate having a front surface and a back surface, wherein multiple sets of front conductive pads are formed on the front surface and multiple sets of back conductive pads are formed on the back surface;
attaching back conductive blocks onto the back surface of the package substrate via back solder bumps, wherein each of the back conductive blocks is aligned with one of the sets of back conductive pads;
loading the package substrate on a first bottom chase with the back conductive blocks facing upward, and pressing, with a first top chase, the back conductive blocks against the first bottom chase to reshape the back solder bumps and horizontally align top surfaces of the back conductive blocks with each other;
forming a back mold cap between the package substrate and the first top mold chase;
attaching front conductive blocks onto the front surface of the package substrate via front solder bumps, wherein each of the front conductive blocks is aligned with one of the sets of front conductive pads;
loading the package substrate on a second bottom chase with the front conductive blocks facing upward, and pressing, with a second top chase, the front conductive blocks against the second bottom chase to reshape the front solder bumps and horizontally align top surfaces of the front conductive blocks with each other; and
forming a front mold cap between the package substrate and the second top mold chase.

2. The method of claim 1, wherein before loading the package substrate on the first bottom chase, the method further comprises: attaching at least one back electronic component onto the back surface of the package substrate, wherein the back conductive blocks are thicker than the back electronic component.

3. The method of claim 1, wherein before loading the package substrate on the second bottom chase, the method further comprises: attaching at least one front electronic component onto the front surface of the package substrate, wherein the front conductive blocks are thicker than the front electronic component.

4. The method of claim 1, wherein after forming a back mold cap and forming a front mold cap, the top surfaces of the front conductive blocks are exposed from a top surface of the front mold cap, and the top surfaces of the back conductive blocks are exposed from a top surface of the back mold cap.

5. The method of claim 1, wherein the front and back conductive blocks are e-bar blocks.

6. The method of claim 1, wherein the front solder bumps on each set of front conductive pads are reshaped but not connected with each other after the step for pressing the front conductive blocks, and the back solder bumps on each set of back conductive pads are reshaped but not connected with each other after the step for pressing the back conductive blocks.

7. A method for forming an electronic package assembly, comprising:
providing a package substrate having a front surface and a back surface, wherein multiple sets of front conductive pads are formed on the front surface and multiple sets of back conductive pads are formed on the back surface;
attaching front conductive blocks onto the front surface of the package substrate via front solder bumps, wherein each of the front conductive blocks is aligned with one of the sets of front conductive pads;
attaching back conductive blocks onto the back surface of the package substrate via back solder bumps, wherein each of the back conductive blocks is aligned with one of the sets of back conductive pads;
loading the package substrate between a top chase and a bottom chase, and pressing the front and back conductive blocks against the package substrate with the top chase and the bottom chase to reshape the front and back solder bumps, horizontally align top surfaces of the front conductive blocks with each other and horizontally align top surfaces of the back conductive blocks with each other;
forming a front mold cap between the front surface of the package substrate and the top chase; and
forming a back mold cap between the back surface of the package substrate and the bottom chase.

8. The method of claim 7, wherein before loading the package substrate between the top chase and the bottom chase, the method further comprises: attaching at least one front electronic component onto the front surface of the package substrate, wherein the front conductive blocks are thicker than the at least one front electronic component.

9. The method of claim 7, wherein before loading the package substrate between the top chase and the bottom chase, the method further comprises: attaching at least one back electronic component onto the back surface of the package substrate, wherein the back conductive blocks are thicker than the at least one back electronic component.

10. The method of claim 7, wherein before attaching the front conductive blocks onto the front surface of the package substrate, the back conductive blocks are attached onto the back surface of the package substrate; and wherein before attaching the front conductive blocks onto the front surface of the package substrate, the method further comprises:
loading the package substrate on a bottom chase with the back conductive blocks facing upward; and
pressing, with a top chase, the back conductive blocks against the bottom chase to reshape the back solder bumps and horizontally align the top surfaces of the back conductive blocks with each other.

11. The method of claim 7, wherein the top chase comprises a top base plate and a top flexible film, and the top flexible film is in contact with the top surfaces of the front conductive blocks during the pressing step.

12. The method of claim 7, wherein the bottom chase comprises a bottom base plate and a bottom flexible film, and the bottom flexible film is in contact with the top surfaces of the back conductive blocks during the pressing step.

13. The method of claim 7, wherein the front and back conductive blocks are e-bar blocks.

14. The method of claim 7, wherein the front solder bumps on each set of front conductive pads and the back solder bumps on each set of back conductive pads are reshaped but not connected with each other after the step for pressing the front and back conductive blocks.

15. The method of claim 7, wherein the method further comprises:
forming solder bumps on the top surfaces of the back conductive blocks.

16. The method of claim 7, wherein after forming the front mold cap and forming the back mold cap, the top surfaces of the front conductive blocks are exposed from a top surface of the front mold cap, and the top surfaces of the back conductive blocks are exposed from a top surface of the back mold cap.

17. The method of claim 16, wherein the method further comprises:
mounting an upper electronic component onto the top surfaces of the front conductive blocks.

18. The method of claim 17, wherein the upper electronic component comprises a pre-molded electronic package.

19. An electronic package assembly which is formed using the method of claim 1.

20. An electronic package assembly which is formed using the method of claim 7.
